(19) United States
(12) Patent Application Publication
(10) Pub. No.: US 2025/0316548 A1
(43) Pub. Date: Oct. 9, 2025

(54) CHIP PACKAGE AND MANUFACTURING METHOD THEREOF

(71) Applicant: Xintec Inc., Taoyuan City (TW)

(72) Inventors: Wei-Ming CHIEN, Taoyuan City (TW); Po Han LEE, Taipei City (TW); Tsang-Yu LIU, Zhubei City (TW)

(21) Appl. No.: 19/067,527

(22) Filed: Feb. 28, 2025

Related U.S. Application Data
(60) Provisional application No. 63/631,956, filed on Apr. 9, 2024.

(51) Int. Cl. H01L 23/31; H01L 21/56; H01L 21/78; H01L 23/00; H01L 23/13; H01L 23/14

(52) U.S. Cl. CPC H01L 23/3135; H01L 21/56; H01L 21/78; H01L 23/13; H01L 23/14; H01L 24/13; H01L 24/32; H01L 24/73; H01L 2224/13024; H01L 2224/32225; H01L 2224/73153

(57) ABSTRACT

A chip package includes a light transmissive sheet, a semiconductor substrate, an isolation layer, a redistribution layer, a protection layer, a conductive structure, and a molding compound. The semiconductor substrate is located on the light transmissive sheet. The isolation layer is located on a surface of the semiconductor substrate facing away from the light transmissive sheet. The redistribution layer is located on the isolation layer. The redistribution layer is located in the protection layer. The conductive structure is located on the redistribution layer in the protection layer. The molding compound is located on the protection layer and surrounds the conductive structure. A surface of the molding compound facing away from the protection layer is coplanar with a surface of the conductive structure facing away from the redistribution layer.

### CROSS-REFERENCE TO RELATED APPLICATION

This application claims priority to U.S. Provisional Application Ser. No. 63/631,956, filed Apr. 9, 2024, which is herein incorporated by reference.

### BACKGROUND

### Field of Invention

The present disclosure relates to a chip package and a manufacturing method of the chip package.

### Description of Related Art

Generally speaking, a chip package for image sensing includes a light transmissive sheet and a semiconductor substrate with a sensing area. In addition, the chip package may also include a redistribution layer, a solder ball, and a protection layer (such as green paint).

However, the protection layer of the above-mentioned chip package is patterned to form openings first, and then the ball grid array (BGA) process is performed. As a result, most of the volume of the solder ball is located outside the protection layer, such that the protection layer is difficult to provide protection and support for the solder ball, which is not conducive to the steps after wafer dicing. Moreover, during the manufacturing of the chip package, the process of grinding the light transmissive sheet may be necessary to perform. However, the material strength and thickness of the protection layer are insufficient, and thus grinding the light transmissive sheet may cause peeling or disconnection of layers, such that the yield rate is difficult to be improved.

### SUMMARY

According to some embodiments of the present disclosure, a chip package includes a light transmissive sheet, a semiconductor substrate, an isolation layer, a redistribution layer, a protection layer, a conductive structure, and a molding compound. The semiconductor substrate is located on the light transmissive sheet. The isolation layer is located on a surface of the semiconductor substrate facing away from the light transmissive sheet. The redistribution layer is located on the isolation layer. The redistribution layer is located in the protection layer. The conductive structure is located on the redistribution layer in the protection layer. The molding compound is located on the protection layer and surrounds the conductive structure. A surface of the molding compound facing away from the protection layer is coplanar with a surface of the conductive structure facing away from the redistribution layer.

In some embodiments, a material of the protection layer is different from a material of the molding compound.

In some embodiments, a sidewall of the light transmissive sheet has a recess, and the protection layer covers a sidewall of the semiconductor substrate and extends to the recess of the light transmissive sheet.

In some embodiments, the molding compound covers a sidewall of the semiconductor substrate and a sidewall of the light transmissive sheet.

In some embodiments, the sidewall of the light transmissive sheet has a recess, and the molding compound covers the recess.

In some embodiments, a ratio of a thickness of the protection layer on the isolation layer to a thickness of the molding compound on the protection layer is in a range from 1:3 to 1:50.

In some embodiments, the semiconductor substrate has a through hole and a conductive pad in the through hole, and the redistribution layer extends onto the conductive pad in the through hole.

In some embodiments, a portion of the protection layer extends to the redistribution layer in the through hole to define an adjoining position, and a ratio of a thickness of the semiconductor substrate to a distance between the surface of the semiconductor substrate and the adjoining position is in a range from 3:1 to 20:1.

In some embodiments, the chip package further includes a bonding layer between the semiconductor substrate and the light transmissive sheet.

In some embodiments, a sidewall of the bonding layer is in contact with the protection layer.

In some embodiments, a sidewall of the bonding layer is in contact with the molding compound.

According to some embodiments of the present disclosure, a manufacturing method of a chip package includes bonding a light transmissive sheet on the a semiconductor substrate; forming an isolation layer on a surface of the semiconductor substrate facing away from the light transmissive sheet; forming a redistribution layer on the isolation layer; forming a scribe line in the semiconductor substrate and the light transmissive sheet; forming a protection layer on the isolation layer and in the scribe line; forming a conductive structure on the redistribution layer; forming a molding compound on the protection layer and in the scribe line, wherein the molding compound surrounds the conductive structure; grinding the molding compound and the conductive structure such that a surface of the molding compound facing away from the protection layer is coplanar with a surface of the conductive structure facing away from the redistribution layer; and cutting the molding compound and the light transmissive sheet along the scribe line.

In some embodiments, the manufacturing method of the chip package further includes after forming the protection layer on the isolation layer and in the scribe line, forming a trench in the protection layer in the scribe line. In some embodiments, the trench is formed by laser grooving.

In some embodiments, the manufacturing method of the chip package further includes after grinding the molding compound and the conductive structure, testing signals of the conductive structure and the redistribution layer.

According to some embodiments of the present disclosure, a manufacturing method of a chip package includes bonding a light transmissive sheet on the a semiconductor substrate; forming an isolation layer on a surface of the semiconductor substrate facing away from the light transmissive sheet; forming a redistribution layer on the isolation layer; forming a protection layer on the isolation layer, wherein the redistribution layer is located in the protection layer; forming a conductive structure on the redistribution layer; forming a scribe line in the semiconductor substrate and the light transmissive sheet; forming a molding compound on the protection layer and in the scribe line, wherein the molding compound surrounds the conductive structure; grinding the molding compound and the conductive structure such that a surface of the molding compound facing away from the protection layer is coplanar with a surface of the conductive structure facing away from the redistribution layer; forming a trench in the molding compound in the scribe line; and grinding a surface of the light transmissive sheet facing away from the semiconductor substrate.

In some embodiments, forming the scribe line in the semiconductor substrate and the light transmissive sheet further includes forming an upper portion of the scribe line in the semiconductor substrate and the light transmissive sheet; and forming a lower portion of the scribe line in the light transmissive sheet, wherein a width of the lower portion is less than a width of the upper portion.

In some embodiments, the upper portion and the lower portion of the scribe line are respectively formed by using a first cutting tool and a second cutting tool, and a width of the first cutting tool is greater than a width of the second cutting tool.

In some embodiments, forming the trench in the molding compound in the scribe line is performed such that the light transmissive sheet is exposed.

In some embodiments, the trench is formed by laser grooving.

In the aforementioned embodiments of the present disclosure, since the molding compound is located on the protection layer and surrounds the conductive structure, the molding compound can provide a supporting force for the conductive structure and improve the strength of the entire chip package, which facilitate wafer dicing and the following manufacturing process in chip scale to meet client needs. In addition, during the manufacture of the chip package, the molding compound may be filled into the scribe line and then grinding the light transmissive sheet is performed. As a result, the material strength and the thickness of the molding compound is sufficient and the molding compound has good hole filling property, thereby preventing peeling or disconnection of layers when grinding the light transmissive sheet to improve the yield rate of products.

According to some embodiments of the present disclosure, a chip package includes a semiconductor substrate, a light transmissive sheet, a conductive structure, and a molding compound. The semiconductor substrate has two surfaces opposite to each other. The light transmissive sheet covers one of the two surfaces of the semiconductor substrate. The conductive structure is located on another one of the two surfaces of the semiconductor substrate. The molding compound surrounds the light transmissive sheet, the semiconductor substrate, and the conductive structure, wherein a surface of the conductive structure facing away from the semiconductor substrate is coplanar with a surface of the molding compound.

In some embodiments, a surface of the light transmissive sheet facing away from the semiconductor substrate is coplanar with another surface of the molding compound.

According to some embodiments of the present disclosure, a manufacturing method of a chip package includes forming a temporary bonding layer on a carrier; forming at least one semiconductor structure comprising a semiconductor substrate, a light transmissive sheet, and a conductive structure, wherein the light transmissive sheet covers one of two surfaces of the semiconductor substrate opposite to each other, and the conductive structure is located on another one of the two surfaces of the semiconductor substrate; bonding the light transmissive sheet of the semiconductor structure on the carrier by using the temporary bonding layer; forming a molding compound surrounding the light transmissive sheet, the semiconductor substrate, and the conductive structure; grinding the molding compound and the conductive structure such that a surface of the conductive structure facing away from the semiconductor substrate is coplanar with a surface of the molding compound; removing the temporary bonding layer and the carrier; and cutting the molding compound.

In some embodiments, removing the temporary bonding layer and the carrier is performed such that a surface of the light transmissive sheet facing away from the semiconductor substrate is coplanar with another surface of the molding compound.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a chip package according to one embodiment of the present disclosure.

FIGS. 2 to 8 are cross-sectional views at intermediate stages of a manufacturing method of a chip package according to one embodiment of the present disclosure.

FIGS. 9 to 14 are cross-sectional views at intermediate stages of a manufacturing method of a chip package according to another embodiment of the present disclosure.

FIG. 15 is a cross-sectional view of a chip package according to one embodiment of the present disclosure.

FIGS. 16 to 18 are cross-sectional views at intermediate stages of the manufacturing method of the chip package of FIG. 15.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

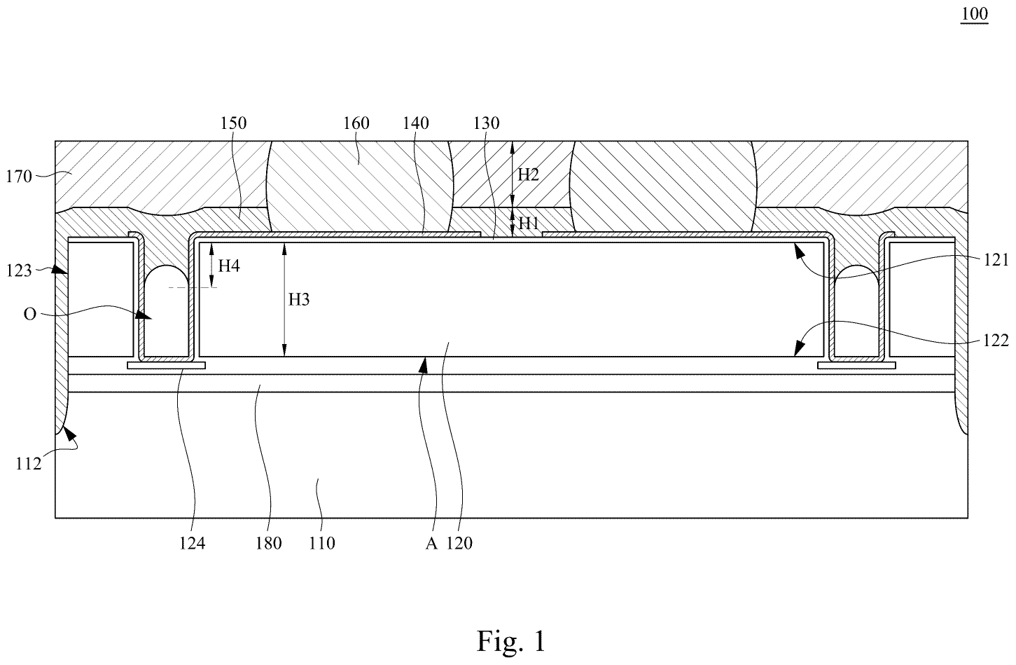

FIG. 1 is a cross-sectional view of a chip package 100 according to one embodiment of the present disclosure. The chip package 100 includes a light transmissive sheet 110, a semiconductor substrate 120, an isolation layer 130, a redistribution layer 140, a protection layer 150, a conductive structure 160, and a molding compound 170. The semiconductor substrate 120 is located on the light transmissive sheet 110. A surface 122 of the semiconductor substrate 120 has a sensing area A, such as an image sensing device. The isolation layer 130 is located on a surface 121 of the semiconductor substrate 120 facing away from the light transmissive sheet 110. The redistribution layer 140 is located on the isolation layer 130, and is located in the protection layer 150. The conductive structure 160 is located on the redistribution layer 140 in the protection layer 150. The molding compound 170 is located on the protection layer 150 and surrounds the conductive structure 160. The surface of the molding compound 170 facing away from the protection layer 150 is coplanar with the surface of the conductive structure 160 facing away from the redistribution layer 140. In other words, the top surface of the molding compound 170 and the top surface of the conductive structure 160 shown in FIG. 1 cooperatively define a horizontal surface.

In some embodiments, the light transmissive sheet 110 may be an optical glass capable of filtering light. The material of the semiconductor substrate 120 may include silicon, such as a silicon substrate. The semiconductor substrate 120 may further have a conductive pad 124 and a through hole O. The conductive pad 124 is located on the surface 122 of the semiconductor substrate 120, and is located in the through hole O. The redistribution layer 140 extends onto the conductive pad 124 in the through hole O so as to achieve electrical connections. The material of the protection layer 150 is different from the material of the molding compound 170. For example, the protection layer 150 is solder mask green paint, and there is an interface between the protection layer 150 and the molding compound 170.

Since the molding compound 170 is located on the protection layer 150 and surrounds the conductive structure 160, the molding compound 170 can provide a supporting force for the conductive structure 160 and improve the strength of the entire chip package 100, which facilitate wafer dicing and the following manufacturing process in chip scale to meet client needs.

In this embodiment, the sidewall of the light transmissive sheet 110 has a recess 112, and the protection layer 150 covers a sidewall 123 of the semiconductor substrate 120 and extends to the recess 112 of the light transmissive sheet 110. Such a design can improve lateral protection for the chip package 100.

Moreover, a ratio of a thickness H1 of the protection layer 150 on the isolation layer 130 to a thickness H2 of the molding compound 170 on the protection layer 150 is in a range from 1:3 to 1:50. A thickness H2 of the molding compound 170 may be less than 300 μm. Through the aforementioned design, the stability of the conductive structure 160 can be improved. Furthermore, the semiconductor substrate 120 has a thickness H3 which may be in a range from 30 μm to 300 μm. A portion of the protection layer 150 extends to the redistribution layer 140 in the through hole O to define an adjoining position, a distance H4 is between the surface 121 of the semiconductor substrate 120 and said adjoining position, and a ratio of the thickness H3 of the semiconductor substrate 120 to the aforesaid distance H4 is in a range from 3:1 to 20:1. The thickness of the light transmissive sheet 110 may be in a range from 30 μm to 1000 μm.

In some embodiments, the chip package 100 further includes a bonding layer 180. The bonding layer 180 is located between the semiconductor substrate 120 and the light transmissive sheet 110. The sidewall of the bonding layer 180 is in contact with the protection layer 150.

It is to be noted that the connection relationships, the materials, and the advantages of the elements described above will not be repeated in the following description. In the following description, the manufacturing method of the chip package 100 will be explained.

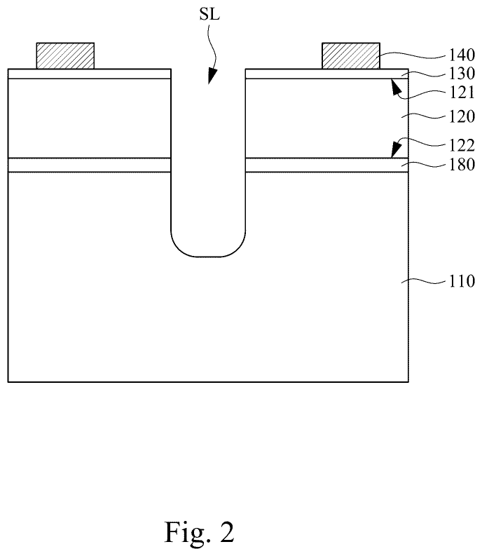

FIGS. 2 to 8 are cross-sectional views at intermediate stages of a manufacturing method of a chip package according to one embodiment of the present disclosure. As shown in FIG. 2, the light transmissive sheet 110 is bonded on the surface 122 of the semiconductor substrate 120 by utilizing the bonding layer 180. The semiconductor substrate 120 shown in FIGS. 2 to 7 is in wafer level, and is not yet diced. Thereafter, the isolation layer 130 is formed on the surface 121 of the semiconductor substrate 120 facing away from the light transmissive sheet 110, and the redistribution layer 140 is formed on the isolation layer 130. Thereafter, a scribe line SL is formed in the semiconductor substrate 120 and the light transmissive sheet 110. As a result, the structure of FIG. 2 can be obtained.

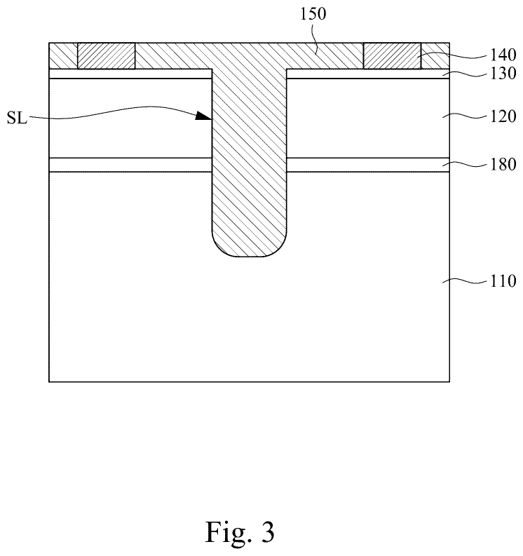

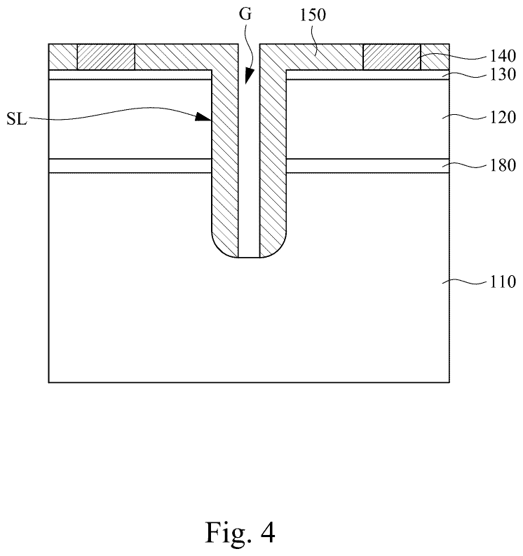

As shown in FIG. 3 and FIG. 4, after the formation of the scribe line SL, the protection layer 150 is formed on the isolation layer 130 and in the scribe line SL. The scribe line SL is filled with the protection layer 150. After the protection layer 150 is formed on the isolation layer 130 and in the scribe line SL, a trench G is formed in the protection layer 150 in the scribe line SL, such that a portion of the light transmissive sheet 110 is exposed through the trench G. In some embodiments, the trench G is formed by laser grooving. The trench G is located in the central position of the scribe line SL.

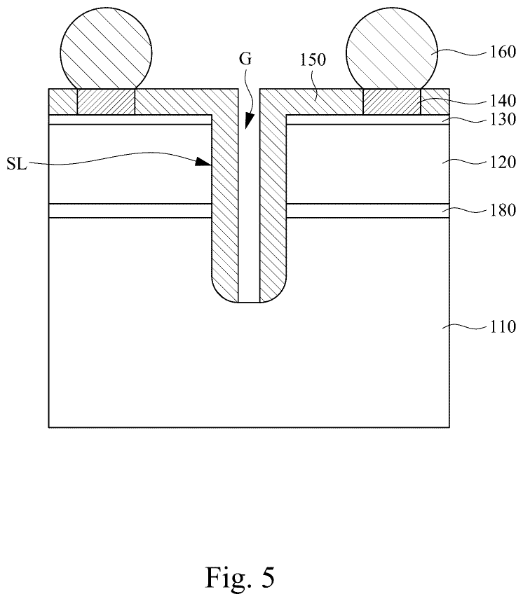

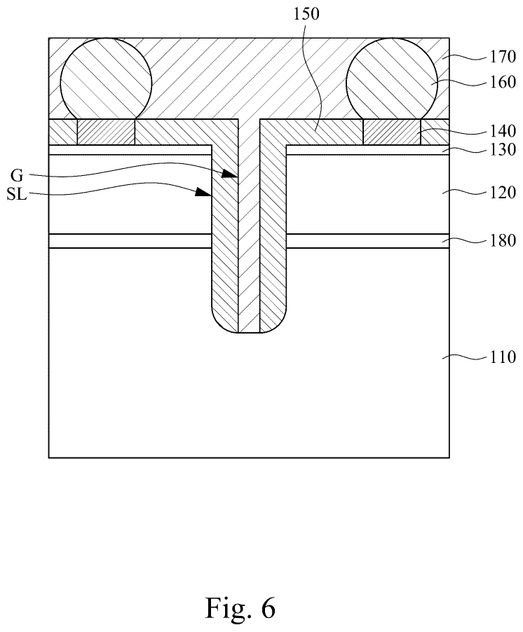

As shown in FIG. 5 and FIG. 6, after the formation of the trench G, the conductive structure 160 is formed on the redistribution layer 140 in the protection layer 150. The conductive structure 160 may be, but not limited to a solder ball. Thereafter, the molding compound 170 is formed on the protection layer 150 and in the scribe line SL, and the molding compound 170 surrounds the conductive structure 160. Moreover, the trench G is filled with the molding compound 170, such that the bottom end of the molding compound 170 is in contact with the light transmissive sheet 110. The molding compound 170 is dry film.

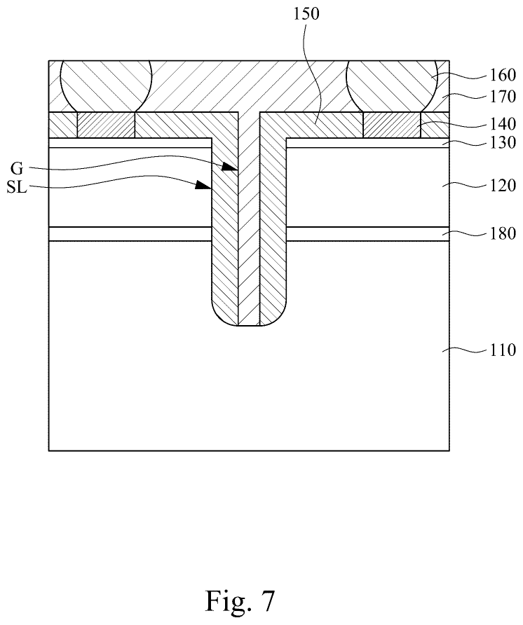

As shown in FIG. 7, after the formation of the molding compound 170, grinding the molding compound 170 and the conductive structure 160 may be performed, such that the surface of the molding compound 170 facing away from the protection layer 150 is coplanar with the surface of the conductive structure 160 facing away from the redistribution layer 140. In other words, the top surface of the molding compound 170 and the top surface of the conductive structure 160 shown in FIG. 7 cooperatively define a horizontal surface. After grinding the molding compound 170 and the conductive structure 160, the top surface of the conductive structure 160 is exposed, and thus the signals of the conductive structure 160 and the redistribution layer 140 can be tested, such as wafer acceptance test (WAT), to ensure product quality.

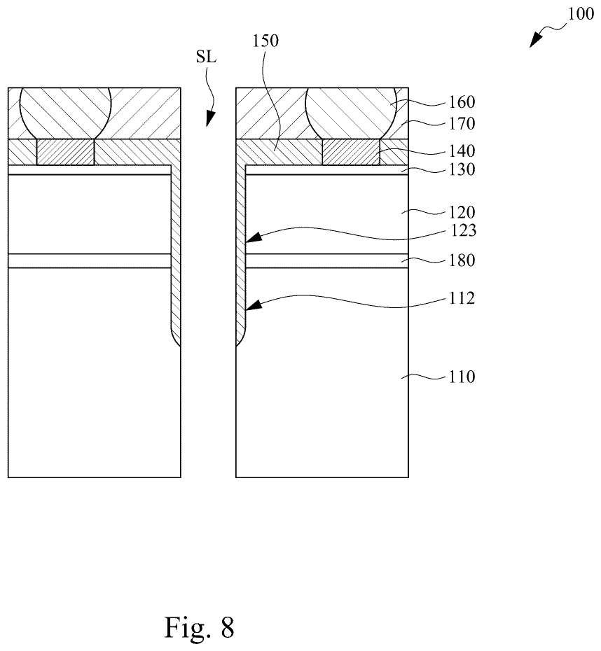

As shown in FIG. 8, thereafter, the molding compound 170, the protection layer 150, and the light transmissive sheet 110 can be cut along the scribe line SL (e.g., the trench G in the scribe line SL). As a result, the chip package 100 can be obtained (may also see the edge region of the chip package 100 in FIG. 1). The sidewall of the light transmissive sheet 110 of the chip package 100 has the recess 112, and the protection layer 150 extends from the isolation layer 130 to the recess 112 of the light transmissive sheet 110 along the sidewall 123 of the semiconductor substrate 120 and the sidewall of the bonding layer 180 in sequence. In some embodiments, the step of forming the trench G shown in FIG. 4 may be omitted to directly perform the steps shown in FIGS. 5 to 8.

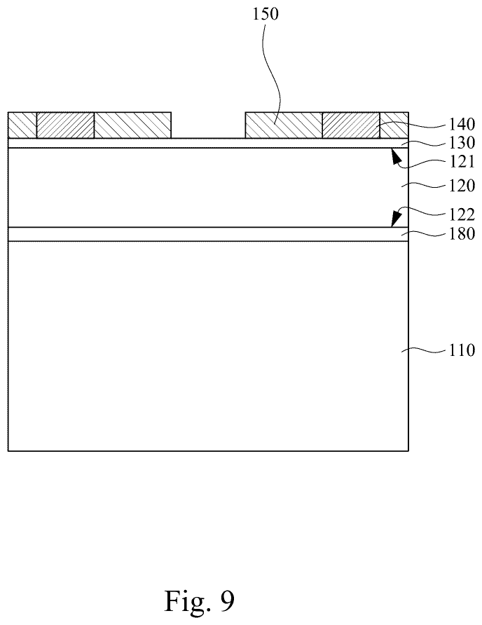

FIGS. 9 to 14 are cross-sectional views at intermediate stages of a manufacturing method of a chip package according to another embodiment of the present disclosure. As shown in FIG. 9, the light transmissive sheet 110 is bonded on the surface 122 of the semiconductor substrate 120 by utilizing the bonding layer 180. The semiconductor substrate 120 shown in FIGS. 9 to 13 is in wafer level, and is not yet diced. Thereafter, the isolation layer 130 is formed on the surface 121 of the semiconductor substrate 120 facing away from the light transmissive sheet 110, and the redistribution layer 140 is formed on the isolation layer 130. Thereafter, the protection layer 150 is formed on the isolation layer 130, such that the redistribution layer 140 is located in the protection layer 150. As a result, the structure of FIG. 9 can be obtained.

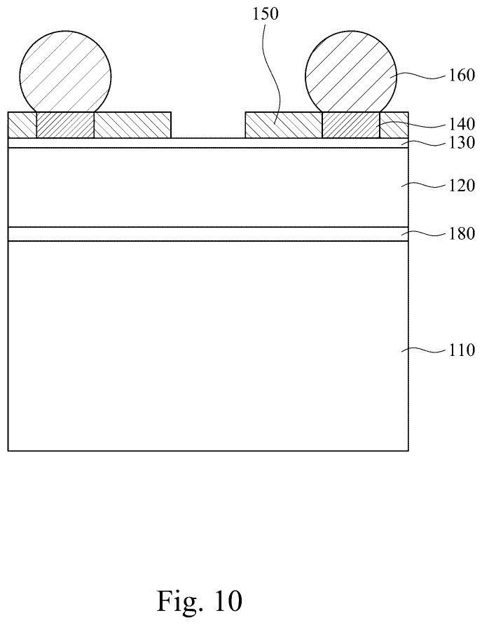

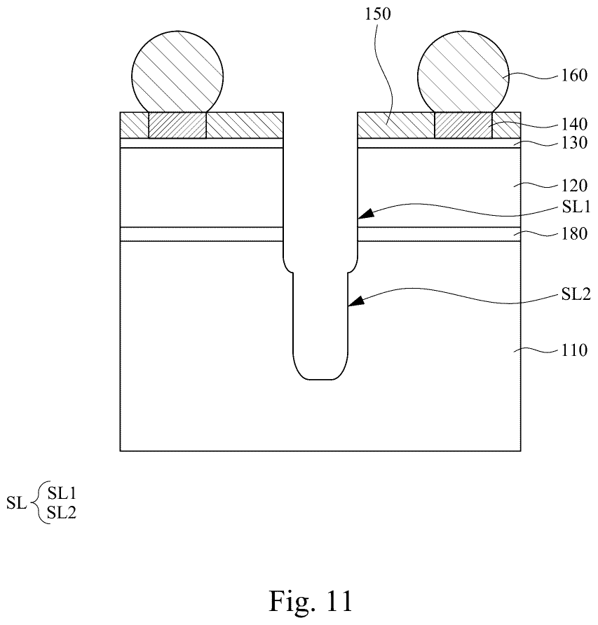

As shown in FIG. 10 and FIG. 11, after the formation of the protection layer 150, the conductive structure 160 is formed on the redistribution layer 140. Thereafter, the scribe line SL is formed in the semiconductor substrate 120 and the light transmissive sheet 110. In this step, an upper portion SL1 of the scribe line SL is formed in the semiconductor substrate 120 and the light transmissive sheet 110, and then a lower portion SL2 of the scribe line SL is formed in the light transmissive sheet 110, in which the width of the lower portion SL2 is less than the width of the upper portion SL1. In some embodiments, the upper portion SL1 and the lower portion SL2 of the scribe line SL are respectively formed by using a first cutting tool and a second cutting tool, and the width of the first cutting tool is greater than the width of the second cutting tool, such that the upper portion SL1 is wider than the lower portion SL2.

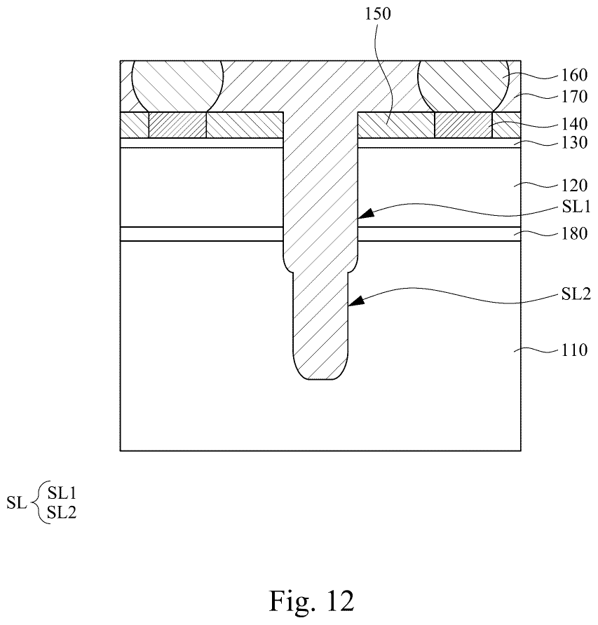

As shown in FIG. 12, after the formation of the scribe line SL, the molding compound 170 is formed on the protection layer 150 and in the scribe line SL, in which the molding compound 170 surrounds the conductive structure 160. The scribe line SL is filled with the molding compound 170. After the formation of the molding compound 170, grinding the molding compound 170 and the conductive structure 160 may be performed, such that the surface of the molding compound 170 facing away from the protection layer 150 is coplanar with the surface of the conductive structure 160 facing away from the redistribution layer 140. In other words, the top surface of the molding compound 170 and the top surface of the conductive structure 160 shown in FIG. 7 cooperatively define a horizontal surface. After grinding the molding compound 170 and the conductive structure 160, the top surface of the conductive structure 160 is exposed.

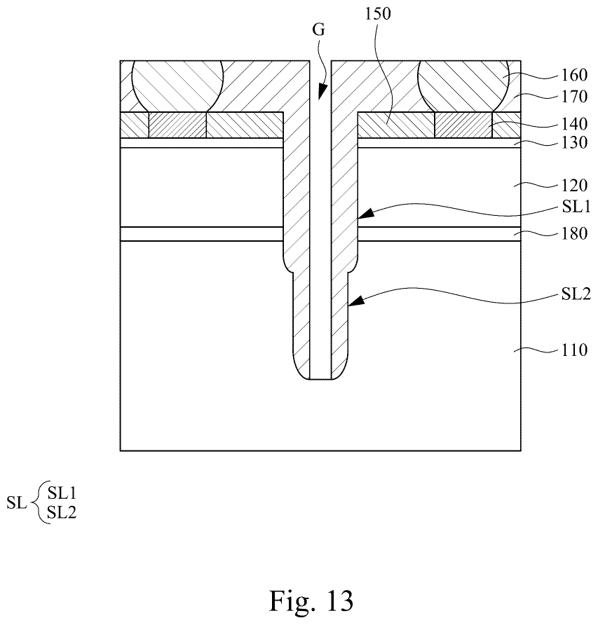

As shown in FIG. 13, thereafter, the trench G is formed in the molding compound 170 in the scribe line SL, such that a portion of the light transmissive sheet 110 is exposed through the trench G. In some embodiments, the trench G is formed by laser grooving. The trench G is located in the central position of the scribe line SL.

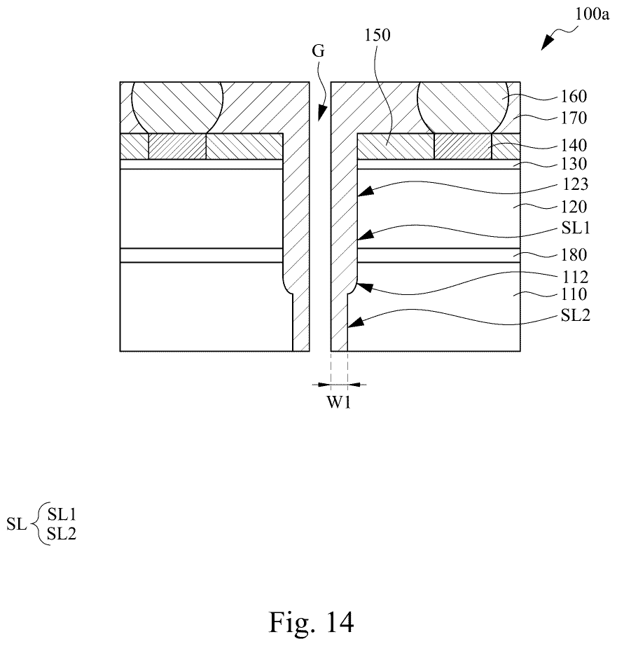

As shown in FIG. 14, after the formation of the trench G, grinding the surface of the light transmissive sheet 110 facing away from the semiconductor substrate 120 (i.e., the bottom surface of the light transmissive sheet 110 of FIG. 13) may be performed. When grinding to the bottom end of the trench G of FIG. 13, the light transmissive sheet 110 is divided, thereby obtaining a chip package 100a (capable of replacing the edge region of the chip package 100 of FIG. 1). The sidewall of the light transmissive sheet 110 of the chip package 100a has the recess 112, and the molding compound 170 covers the sidewall 123 of the semiconductor substrate 120, the sidewall of the light transmissive sheet 110, and the recess 112 of the light transmissive sheet 110. In addition, the sidewall of the bonding layer 180 is in contact with the molding compound 170. In other words, the molding compound 170 extends from the isolation layer 130 to the sidewall of the light transmissive sheet 110 along the sidewall 123 of the semiconductor substrate 120, the sidewall of the bonding layer 180, and the recess 112 of the light transmissive sheet 110 in sequence. A width W1 of the molding compound 170 on the sidewall of the light transmissive sheet 110 may be in a range from 10 μm to 100 μm.

During the manufacture of the chip package 100a, the molding compound 170 may be filled into the scribe line SL and then grinding the light transmissive sheet 110 is performed. As a result, the material strength and the thickness of the molding compound 170 is sufficient and the molding compound 170 has good hole filling property, thereby preventing peeling or disconnection of layers when grinding the light transmissive sheet 110 to improve the yield rate of products.

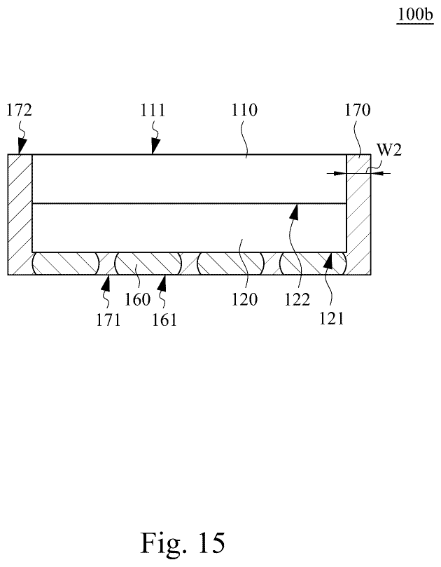

FIG. 15 is a cross-sectional view of a chip package 100b according to one embodiment of the present disclosure. The chip package 100b includes the semiconductor substrate 120, the light transmissive sheet 110, the conductive structure 160, and the molding compound 170. The semiconductor substrate 120 may have the aforementioned isolation layer 130, redistribution layer 140, and protection layer 150. The semiconductor substrate 120 has the two surfaces 121 and 122 opposite to each other. The light transmissive sheet 110 covers the surface 122 of the semiconductor substrate 120. The conductive structure 160 is located on the surface 121 of the semiconductor substrate 120. The molding compound 170 surrounds the light transmissive sheet 110, the semiconductor substrate 120, and the conductive structure 160, and a surface 161 of the conductive structure 160 facing away from the semiconductor substrate 120 is coplanar with a surface 171 of the molding compound 170. Furthermore, a surface 111 of the light transmissive sheet 110 facing away from the semiconductor substrate 120 is coplanar with another surface 172 of the molding compound 170. In some embodiments, a width W2 of the molding compound 170 on the sidewall of the light transmissive sheet 110 and the sidewall of the semiconductor substrate 120 may be in a range from 10 μm to 1000 μm.

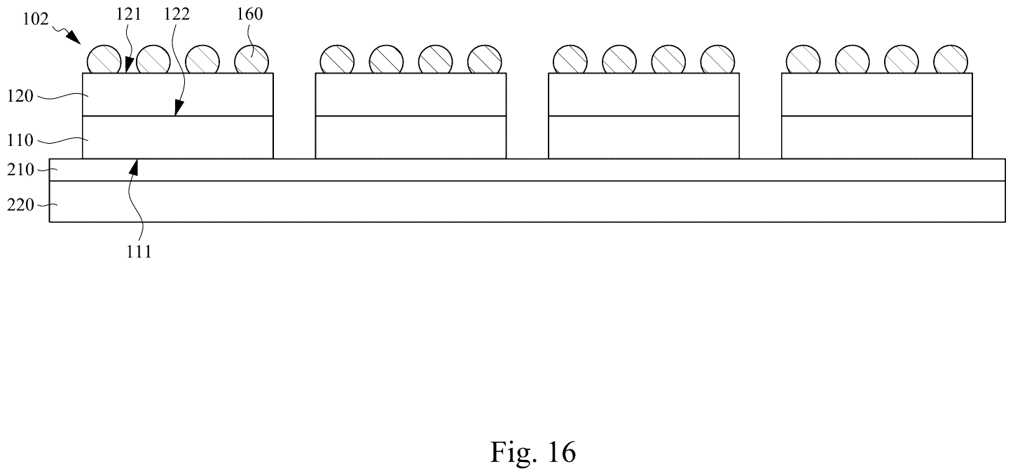

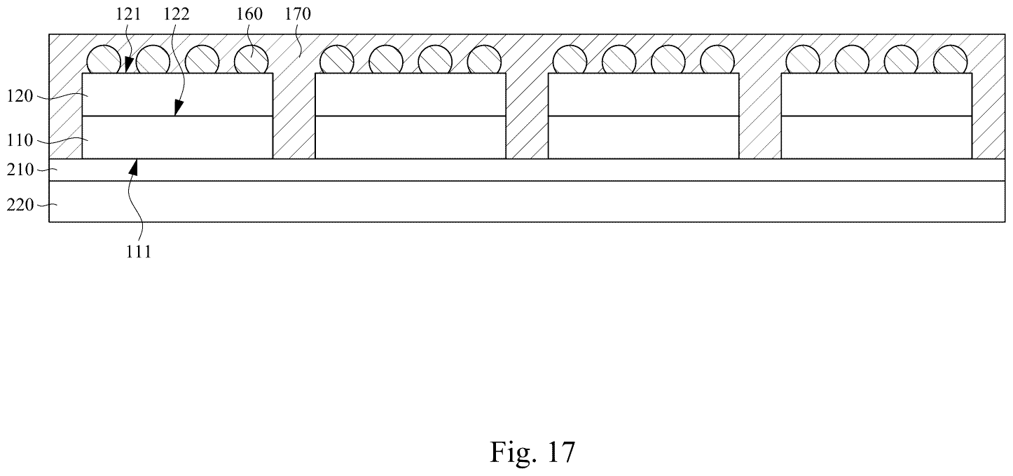

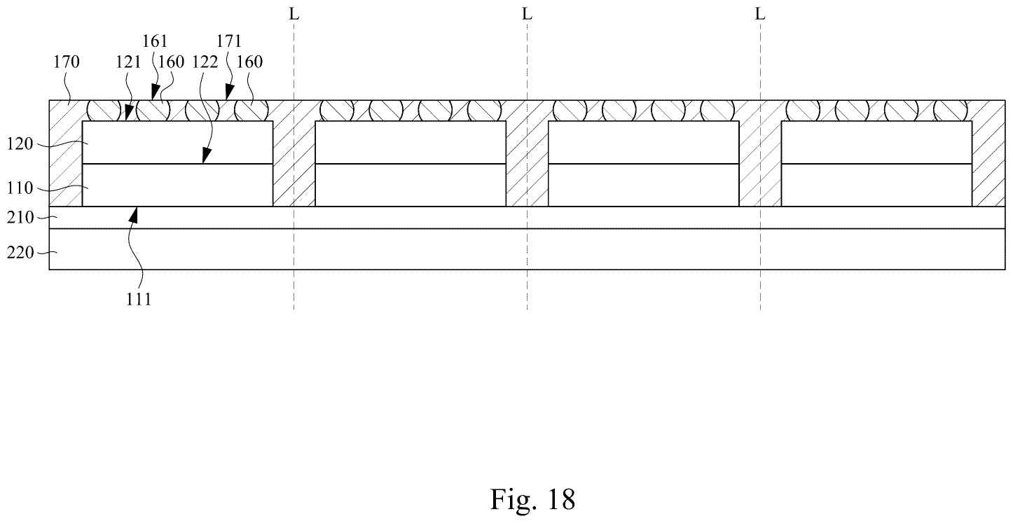

FIGS. 16 to 18 are cross-sectional views at intermediate stages of the manufacturing method of the chip package 100b of FIG. 15. As shown in FIG. 16, a temporary bonding layer 210 is formed on a carrier 220. At least one semiconductor structure 102 including the semiconductor substrate 120, the light transmissive sheet 110, and the conductive structure 160 is formed. The light transmissive sheet 110 covers the surface 121 of the semiconductor substrate 120, and the conductive structure 160 is located on the surface 122 of the semiconductor substrate 120. Thereafter, the light transmissive sheet 110 of the semiconductor structure 102 is bonded on the carrier 220 by using the temporary bonding layer 210. FIG. 16 illustrates four semiconductor structures 102 on the temporary bonding layer 210, but the present disclosure is not limited in this regard. As shown in FIG. 17, thereafter, the molding compound 170 is formed on the temporary bonding layer 210 to surround the light transmissive sheet 110, the semiconductor substrate 120, and the conductive structure 160. As shown in FIG. 18, thereafter, grinding the molding compound 170 and the conductive structure 160 is performed such that the surface 161 of the conductive structure 160 facing away from the semiconductor substrate 120 is coplanar with the surface 171 of the molding compound 170. After grinding the molding compound 170 and the conductive structure 160, the temporary bonding layer 210 and the carrier 220 can be removed, such that the surface 111 of the light transmissive sheet 110 facing away from the semiconductor substrate 120 is coplanar with another surface 172 of the molding compound 170. Thereafter, the molding compound 170 may be cut along a dotted line L, thereby obtaining the chip package 100b of FIG. 15.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip package, comprising:
a light transmissive sheet;
a semiconductor substrate located on the light transmissive sheet;
an isolation layer located on a surface of the semiconductor substrate facing away from the light transmissive sheet;
a redistribution layer located on the isolation layer;
a protection layer, wherein the redistribution layer is located in the protection layer;
a conductive structure located on the redistribution layer in the protection layer; and
a molding compound located on the protection layer and surrounding the conductive structure, wherein a surface of the molding compound facing away from the protection layer is coplanar with a surface of the conductive structure facing away from the redistribution layer.

2. The chip package of claim 1, wherein a material of the protection layer is different from a material of the molding compound.

3. The chip package of claim 1, wherein a sidewall of the light transmissive sheet has a recess, and the protection layer covers a sidewall of the semiconductor substrate and extends to the recess of the light transmissive sheet.

4. The chip package of claim 1, wherein the molding compound covers a sidewall of the semiconductor substrate and a sidewall of the light transmissive sheet.

5. The chip package of claim 4, wherein the sidewall of the light transmissive sheet has a recess, and the molding compound covers the recess.

6. The chip package of claim 1, wherein a ratio of a thickness of the protection layer on the isolation layer to a thickness of the molding compound on the protection layer is in a range from 1:3 to 1:50.

7. The chip package of claim 1, wherein the semiconductor substrate has a through hole and a conductive pad in the through hole, and the redistribution layer extends onto the conductive pad in the through hole.

8. The chip package of claim 7, wherein a portion of the protection layer extends to the redistribution layer in the through hole to define an adjoining position, and a ratio of a thickness of the semiconductor substrate to a distance between the surface of the semiconductor substrate and the adjoining position is in a range from 3:1 to 20:1.

9. The chip package of claim 1, further comprising:
a bonding layer between the semiconductor substrate and the light transmissive sheet.

10. The chip package of claim 9, wherein a sidewall of the bonding layer is in contact with the protection layer.

11. The chip package of claim 9, wherein a sidewall of the bonding layer is in contact with the molding compound.

12. A manufacturing method of a chip package, comprising:
bonding a light transmissive sheet on the a semiconductor substrate;
forming an isolation layer on a surface of the semiconductor substrate facing away from the light transmissive sheet;
forming a redistribution layer on the isolation layer;
forming a scribe line in the semiconductor substrate and the light transmissive sheet;
forming a protection layer on the isolation layer and in the scribe line;
forming a conductive structure on the redistribution layer;
forming a molding compound on the protection layer and in the scribe line, wherein the molding compound surrounds the conductive structure;
grinding the molding compound and the conductive structure such that a surface of the molding compound facing away from the protection layer is coplanar with a surface of the conductive structure facing away from the redistribution layer; and
cutting the molding compound and the light transmissive sheet along the scribe line.

13. The manufacturing method of the chip package of claim 12, further comprising:
after forming the protection layer on the isolation layer and in the scribe line, forming a trench in the protection layer in the scribe line.

14. The manufacturing method of the chip package of claim 13, wherein the trench is formed by laser grooving.

15. The manufacturing method of the chip package of claim 12, further comprising:
after grinding the molding compound and the conductive structure, testing signals of the conductive structure and the redistribution layer.

16. A manufacturing method of a chip package, comprising:
bonding a light transmissive sheet on the a semiconductor substrate;
forming an isolation layer on a surface of the semiconductor substrate facing away from the light transmissive sheet;
forming a redistribution layer on the isolation layer;
forming a protection layer on the isolation layer, wherein the redistribution layer is located in the protection layer;
forming a conductive structure on the redistribution layer;
forming a scribe line in the semiconductor substrate and the light transmissive sheet;
forming a molding compound on the protection layer and in the scribe line, wherein the molding compound surrounds the conductive structure;
grinding the molding compound and the conductive structure such that a surface of the molding compound facing away from the protection layer is coplanar with a surface of the conductive structure facing away from the redistribution layer;
forming a trench in the molding compound in the scribe line; and
grinding a surface of the light transmissive sheet facing away from the semiconductor substrate.

17. The manufacturing method of the chip package of claim 16, wherein forming the scribe line in the semiconductor substrate and the light transmissive sheet further comprises:
forming an upper portion of the scribe line in the semiconductor substrate and the light transmissive sheet; and
forming a lower portion of the scribe line in the light transmissive sheet, wherein a width of the lower portion is less than a width of the upper portion.

18. The manufacturing method of the chip package of claim 17, wherein the upper portion and the lower portion of the scribe line are respectively formed by using a first cutting tool and a second cutting tool, and a width of the first cutting tool is greater than a width of the second cutting tool.

19. The manufacturing method of the chip package of claim 16, wherein forming the trench in the molding compound in the scribe line is performed such that the light transmissive sheet is exposed.

20. The manufacturing method of the chip package of claim 16, wherein the trench is formed by laser grooving.

21. A chip package, comprising:
a semiconductor substrate having two surfaces opposite to each other;
a light transmissive sheet covering one of the two surfaces of the semiconductor substrate;
a conductive structure located on another one of the two surfaces of the semiconductor substrate; and
a molding compound surrounding the light transmissive sheet, the semiconductor substrate, and the conductive structure, wherein a surface of the conductive structure facing away from the semiconductor substrate is coplanar with a surface of the molding compound.

22. The chip package of claim 21, wherein a surface of the light transmissive sheet facing away from the semiconductor substrate is coplanar with another surface of the molding compound.

23. A manufacturing method of a chip package, comprising:
forming a temporary bonding layer on a carrier;
forming at least one semiconductor structure comprising a semiconductor substrate, a light transmissive sheet, and a conductive structure, wherein the light transmissive sheet covers one of two surfaces of the semiconductor substrate opposite to each other, and the conductive structure is located on another one of the two surfaces of the semiconductor substrate;
bonding the light transmissive sheet of the semiconductor structure on the carrier by using the temporary bonding layer;
forming a molding compound surrounding the light transmissive sheet, the semiconductor substrate, and the conductive structure;
grinding the molding compound and the conductive structure such that a surface of the conductive structure facing away from the semiconductor substrate is coplanar with a surface of the molding compound;
removing the temporary bonding layer and the carrier; and
cutting the molding compound.

24. The manufacturing method of the chip package of claim 23, wherein removing the temporary bonding layer and the carrier is performed such that a surface of the light transmissive sheet facing away from the semiconductor substrate is coplanar with another surface of the molding compound.
